(19) United States
(12) Patent Application Publication
(10) Pub. No.: US 2025/0145050 A1
(43) Pub. Date: May 8, 2025

(54) BATTERY MANAGEMENT DEVICE

(71) Applicant: TOYOTA JIDOSHA KABUSHIKI KAISHA, Toyota-shi (JP)

(72) Inventor: Nobuyasu HAGA, Seto-shi (JP)

(73) Assignee: TOYOTA JIDOSHA KABUSHIKI KAISHA, Toyota-shi (JP)

(21) Appl. No.: 18/915,373

(22) Filed: Oct. 15, 2024

(30) Foreign Application Priority Data
Nov. 7, 2023 (JP) 2023-190213

(51) Int. Cl. B60L 58/12; G01R 31/3842; H02J 7/00

(52) U.S. Cl. CPC B60L 58/12; H02J 7/00718; H02J 7/007184; G01R 31/3842

(57) ABSTRACT

A battery management device for managing a battery mounted on a vehicle includes an acquisition unit that acquires, from the vehicle, data including information on a current of the battery and information on activation of the vehicle; a derivation unit that derives, based on the data, an integrated value of a current charged and discharged by the battery and an average value of a current charged and discharged by the battery during an activation period of the latest vehicle; and a determination unit that determines that external charging or replacement of the battery has been performed when the integrated value of the current is less than the first threshold value and the average value of the current is less than the second threshold value.

### CROSS-REFERENCE TO RELATED APPLICATION

This application claims priority to Japanese Patent Application No. 2023-190213 filed on Nov. 7, 2023, incorporated herein by reference in its entirety.

### BACKGROUND

### 1. Technical Field

The present disclosure relates to a battery management device that manages a battery mounted on a vehicle.

### 2. Description of Related Art

WO 2015/151848 discloses a detection device and a detection method capable of accurately detecting that a battery mounted on a vehicle has been replaced.

### SUMMARY

In the detection method described in WO 2015/151848, it is detected that a battery has been replaced using a complex equivalent circuit model. Therefore, there is a problem that the load of the detection process increases or the number of adaptation steps increases. In view of this, there is room for study on the method for detecting replacement of a battery.

The present disclosure provides a battery management device capable of accurately detecting, by a simple method, that a battery has been replaced.

In order to address the above issue, an aspect of the technology of the present disclosure is a battery management device configured to manage a battery mounted on a vehicle. The battery management device includes:
an acquisition unit configured to acquire, from the vehicle, data including information on a current of the battery and information on activation of the vehicle;
a derivation unit configured to derive, based on the data, an integrated value of currents that have been charged and discharged by the battery and an average value of currents charged and discharged by the battery during the latest activation period of the vehicle; and
a determination unit configured to determine that external charging or replacement of the battery has been performed when the integrated value of the currents is smaller than a first threshold value and the average value of the currents is smaller than a second threshold value.

With the battery management device of the present disclosure, it is possible to accurately detect that the external charging or the replacement of the battery has been performed based on the integrated value and the average value of the currents charged and discharged by the battery that can be acquired easily without using the complex equivalent circuit model in which the load of the detection process increases.

### BRIEF DESCRIPTION OF THE DRAWINGS

Features, advantages, and technical and industrial significance of exemplary embodiments of the Disclosure will be described below with reference to the accompanying drawings, in which like signs denote like elements, and wherein:

FIG. 1 is a schematic configuration diagram of a battery management device according to an embodiment of the present disclosure;

FIG. 2 is a processing flowchart of a determination control (first embodiment) for battery replacement or the like executed by the battery management device;

FIG. 3 is an image diagram of a starting voltage and a current integrated value of the battery in the first embodiment;

FIG. 4 is an image diagram of voltage and current average values of a battery;

FIG. 5A is a diagram illustrating a process flow of a battery replacement and the like determination control (second embodiment) executed by a battery management device;

FIG. 5B is a diagram illustrating a process flow of a battery replacement and the like determination control (second embodiment) executed by a battery management device;

FIG. 6 is an image diagram of a starting voltage and a current integrated value of a battery in a second embodiment;

FIG. 7 is a processing flowchart of determination control (third embodiment) for battery replacement and the like executed by the battery management device;

FIG. 8 is an example of a data map for deriving the moving average coefficient α1 used in the third embodiment;

FIG. 9 is an example of a data map for deriving the moving average coefficient α2 used in the third embodiment;

FIG. 10A is a process flow chart of an application of determination control such as battery replacement executed by a battery management device;

FIG. 10B is a process flow chart of an application of determination control such as battery replacement executed by a battery management device; and

FIG. 10C is a process flow chart of an application of determination control such as battery replacement executed by a battery management device.

### DETAILED DESCRIPTION OF EMBODIMENTS

The battery management device of the present disclosure uses a battery state such as an integrated value of charge and discharge current of a battery that can be easily acquired from a battery, an average value of charge and discharge current, and an activation voltage, and detects that the battery has been externally charged or that the battery has been replaced based on a change in the battery state, a tendency of deviation, or the like. Hereinafter, an embodiment of the present disclosure will be described in detail with reference to the drawings.

### Embodiment

### Configuration

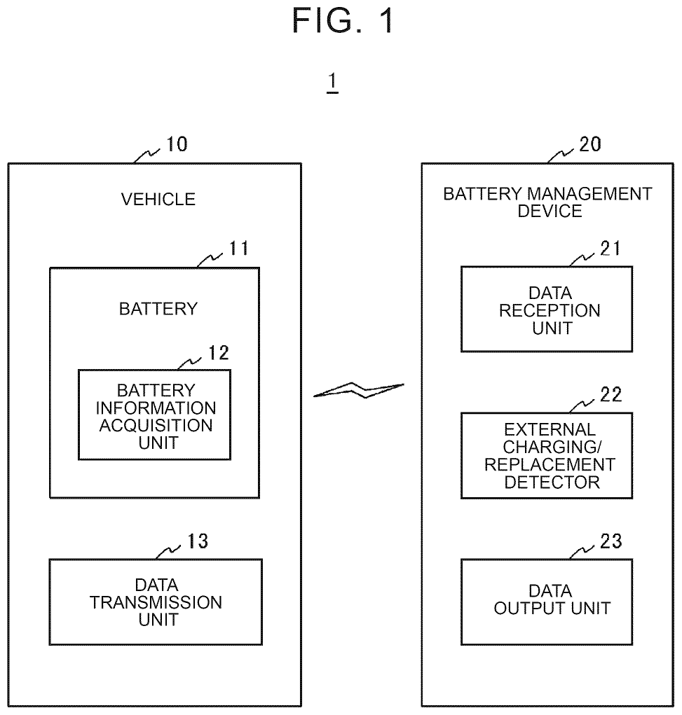

FIG. 1 is a block diagram illustrating a schematic configuration of a battery management system 1 including a battery management device 20 according to an embodiment of the present disclosure. The battery management system 1 illustrated in FIG. 1 includes a vehicle 10 and a battery management device 20 in a configuration.

### (1) Vehicle

The vehicle 10 is communicably connected to the battery management device 20. The vehicle 10 is, for example, an automobile, and includes at least a battery 11, a battery information acquisition unit 12 incorporated in the battery 11, and a data transmission unit 13. Although FIG. 1 illustrates an example in which one vehicle 10 is communicably connected to the battery management device 20, a plurality of vehicles 10 may be communicably connected to the battery management device 20.

The battery 11 is a secondary battery configured to be chargeable and dischargeable, such as a lithium-ion battery or a lead-acid battery. As the battery 11, an auxiliary battery can be exemplified. The battery 11 may be charged, for example, from an external charger via a direct connection by a jumper cable or the like. When the battery 11 deteriorates, it is replaced with a new one.

The battery information acquisition unit 12 acquires battery information related to the state of the battery 11. The battery information includes a voltage, a current (charging current, discharging current), a temperature, and the like of the battery 11. The battery information can be detected by using a detection element (a voltage sensor, a current sensor, a temperature sensor, or the like) (not shown) provided in the battery 11 or the like. Note that the battery information acquisition unit 12 does not need to be built in the battery 11, and may be configured outside the battery 11.

In the present embodiment, the charging current flowing into the battery 11 for charging is defined as a positive value, the discharging current flowing out of the battery 11 for discharging is defined as a negative value, and the current integrated value obtained by summing the charging current and the discharging current is defined as the charging and discharging amount of the battery 11. The charge/discharge amount is defined as “0 (zero)” in a state in which the battery 11 maintains a full charge state (SOC=100%), and is expressed by a negative value smaller than zero in accordance with the remaining capacity of the battery 11.

The data transmission unit 13 has a function of controlling communication between the vehicle 10 and the battery management device 20. The data transmission unit 13 transmits data including the battery information acquired by the battery information acquisition unit 12 and the information related to the activation of the vehicle 10 to the battery management device 20. As the information related to the activation of the vehicle 10, information such as a timing at which the vehicle 10 is activated (at the time of IG-ON), a period during which the vehicle 10 is activated (a period from the activation start to the activation end), and the like can be exemplified. The data transmission unit 13 is realized by, for example, a data communication module (DCM).

### (2) Battery Management Device

The battery management device 20 is communicably connected to the vehicle 10. The battery management device 20 is, for example, a server on the cloud, and includes at least a data reception unit 21, an external charging/replacement detection unit 22, and a data output unit 23.

The data reception unit 21 has a function of controlling communication between the battery management device 20 and the vehicle 10. The data reception unit 21 can receive data transmitted from the vehicle 10.

The external charging/replacement detection unit 22 is configured to detect that the battery 11 has been externally charged and that the battery 11 has been replaced based on data (battery information, activation information) received by the data reception unit 21. Details of the detection method performed by the external charging/replacement detection unit 22 will be described later.

The data output unit 23 can output a message indicating that the battery 11 has been externally charged or that the battery 11 has been replaced by the external charging/replacement detection unit 22. The output destination may be a user of the vehicle 10, a dealer, or the like.

### Control

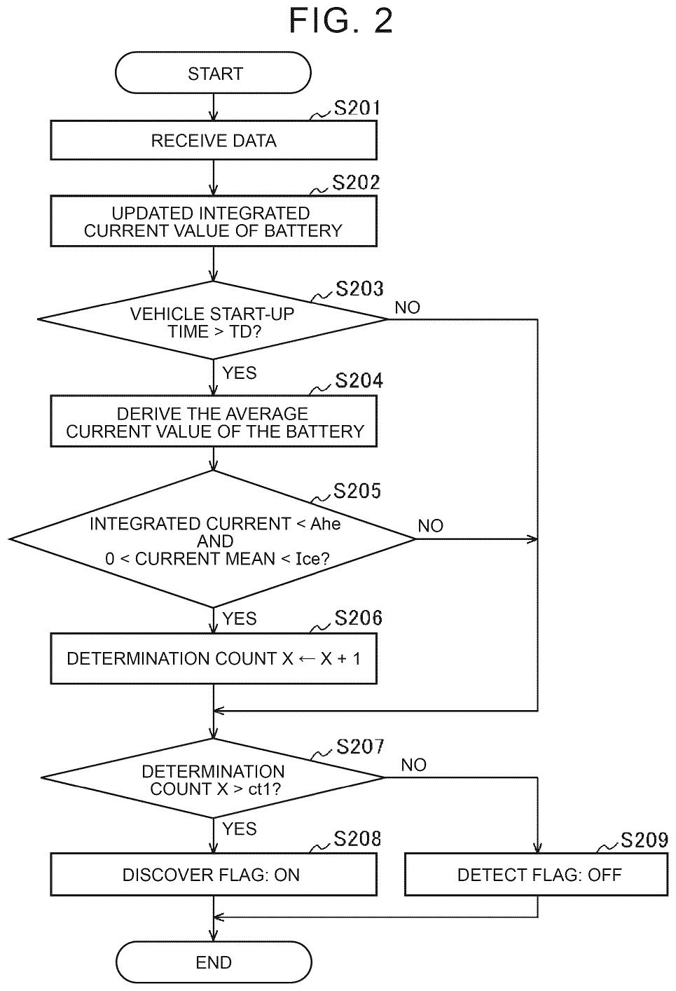

Next, the control performed by the battery management device 20 according to the present embodiment will be described with further reference to FIGS. 2 to 9. Note that the control described below is executed by the battery management device 20 for each vehicle 10.

### (1) First Example

FIG. 2 is a flowchart for explaining a processing procedure of the first embodiment of determination control such as battery replacement executed by the battery management device 20. This first embodiment is a method of utilizing the state of the battery 11 when the vehicle is running. For example, the battery replacement or the like determination control illustrated in FIG. 2 is repeatedly started every time the ignition of the vehicle 10 is turned IG-ON and the vehicle 10 is activated.

### S201

The data reception unit 21 receives data transmitted from the data transmission unit 13 of the vehicle 10. The data received by the data reception unit 21 includes at least information on the current of the battery 11 and information on the activation of the vehicle 10. The received data may be stored in a predetermined storage unit (not shown) or the like. When the data is received by the data reception unit 21, the process proceeds to S202.

### S202

The external charging/replacement detection unit 22 updates (derives) the integrated current value of the battery 11. Specifically, the external charging/replacement detection unit 22 calculates the charge/discharge amount (current value) of the battery 11 from the time of the previous startup to the time of the current startup based on the current (current value) of the battery 11 included in the data received by S201. The calculated charge/discharge amount (current value) is added to the current integrated value of the battery 11 obtained by integrating all the charge/discharge amounts (past values) thus far. When the integrated current of the battery 11 is updated by the external charging/replacement detection unit 22, the process proceeds to S203.

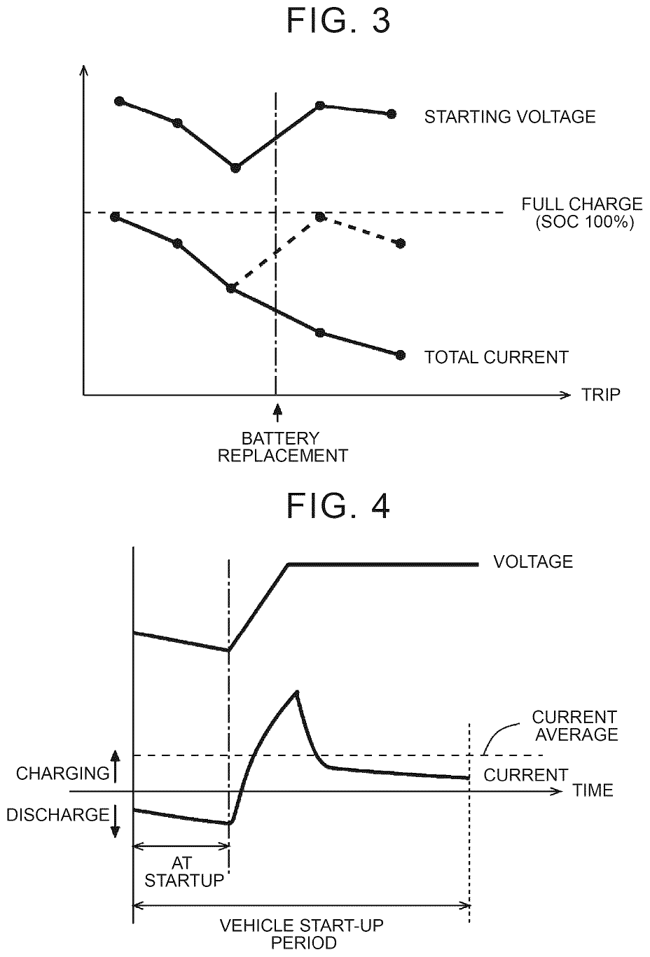

The current integrated value of the battery 11 derived in this S202 indicates that the battery 11 is close to full charge if the absolute value of the negative value is small, and indicates that the battery 11 is far from full charge if the absolute value of the negative value is large, as shown in the lower figure of FIG. 3. FIG. 3 shows an image diagram of the integrated current value of the battery 11. This current integrated value, after the replacement of the battery 11 should be approaching full charge as originally dotted line, but if the replacement cannot be recognized by a sensor or the like it descends like a solid line. In the present embodiment, such misrecognition is eliminated.

### S203

The external charging/replacement detection unit 22 determines whether or not a period (a time period from start-up to start-up end) during which the vehicles 10 are activated exceeds a predetermined time TD (fourth threshold value) based on the data received by S201. This determination is made to determine whether or not the battery is sufficiently charged. Therefore, in the predetermined time TD, a time required for determining that the battery 11 is fully charged is set. When the external charging/replacement detection unit 22 determines that the vehicle-starting period exceeds the time TD (S203, Yes), the process proceeds to S204. On the other hand, when the external charging/replacement detection unit 22 determines that the vehicle-starting period is equal to or less than the time TD (S203, No), the process proceeds to S206.

### S204

The external charging/replacement detection unit 22 derives an average current value of the battery 11. Specifically, the external charging/replacement detection unit 22 derives the mean of the currents charged and discharged by the battery 11 during the start-up period of the most recent vehicle 10, that is, during the period from the start-up to the start-up end of the current time, based on the data received by S201. Since the battery 11 is charged by the rated voltage in the state of being mounted on the vehicle 10, the current average value indicates that the battery 11 is close to full charge when it approaches zero, and indicates that the battery 11 is not fully charged when the value is large. When the mean current of the battery 11 is derived by the external charging/replacement detection unit 22, the process proceeds to S205.

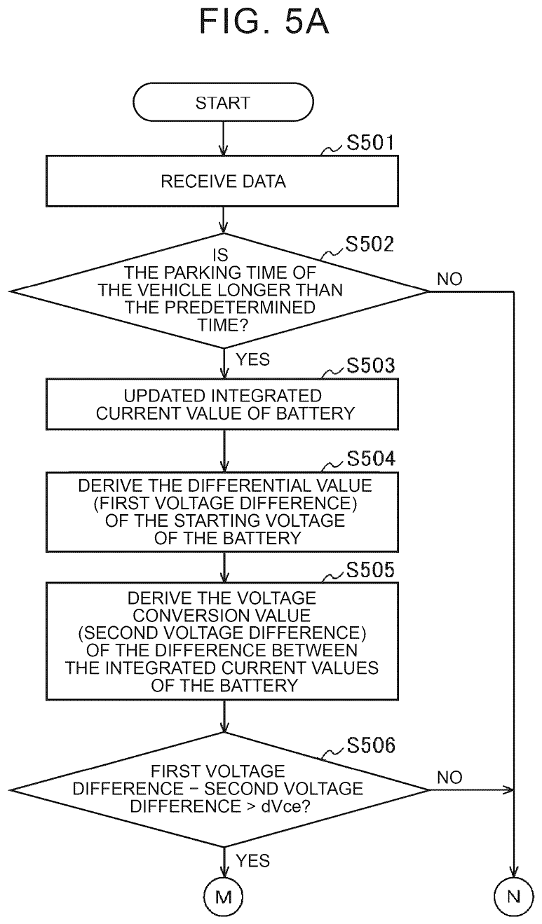

An image of the mean current of the battery 11 derived in this S204 is shown in the lower part of FIG. 4. As illustrated in FIG. 4, the average current value of the battery 11 is an average value of the currents in the vehicle start-up period including the start-up time. If the above-described time TD is short, the effect of the charge current of the battery 11 after the start-up becomes large, and the mean current is pushed up. For this reason, it is desirable to set the time TD to a time at which the effect of the current variation after the start-up becomes sufficiently negligible.

### S205

The external charging/replacement detection unit 22 determines whether or not the integrated current value of the battery 11 is less than the predetermined integrated value Ahe (less than the first threshold value) and the average current value of the battery 11 is greater than zero and less than the predetermined current value Ice (less than the second threshold value). This determination is made in order to determine whether there is any inconsistency between the current integrated value and the current average value with respect to the storage state of the battery 11. The integrated value Ahe is set to an arbitrary value (for example, “10 Ah or less”) that is equal to or larger than the current integrated value that can be obtained when the battery 11 is in a state close to being fully charged. The current value Ice is set to an arbitrary value (for example, “2.5 A”) that is equal to or larger than the current that can be obtained when the battery 11 is nearly fully charged. The integrated value Ahe and the current value Ice are appropriately set based on the capacity and performance of the battery 11, the specifications required for the vehicles 10, and the like. When the external charging/replacement detection unit 22 determines that the current integrated value of the battery 11 is less than the integrated value Ahe and that the current averaged value of the battery 11 is greater than zero and less than the current value Ice (S205, Yes), the process proceeds to S206. On the other hand, when the external charging/replacement detection unit 22 determines that the current integrated value of the battery 11 is equal to or larger than the integrated value Ahe, or that the current averaged value of the battery 11 is equal to or smaller than zero, or that the current value is equal to or larger than the current value Ice (S205, No), the process proceeds to S207.

### S206

The external charging/replacement detection unit 22 increments the determination count X for counting the count that the determination of S205 is “true” by one. The determination count X is cleared by resetting a parameter used for, for example, another logic for determining the rise of the battery 11 based on a determination that the battery 11 has been externally charged or replaced. When the determination count X is incremented by one by the external charging/replacement detection unit 22, the process proceeds to S207.

### S207

The external charging/replacement detection unit 22 determines whether or not the determination count X exceeds a predetermined count ct1 (third threshold value). This determination is performed in order to avoid false detections caused by noises and the like, and the predetermined count ct1 is set to any value (for example, “five times”) that can enhance the determination accuracy. When the external charging/replacement detection unit 22 determines that the determination count X exceeds the count ct1 (S207, Yes), the process proceeds to S208. On the other hand, when the external charging/replacement detection unit 22 determines that the determination count X is equal to or less than the count ct1 (S207, No), the process proceeds to S209.

### S208

The external charging/replacement detection unit 22 turns ON a detection flag indicating that external charging or replacement of the battery 11 has been detected. In response to ON of the detecting flag, the data output unit 23 can perform a required process. When the detection flag is turned ON by the external charging/replacement detection unit 22, the determination control such as the replacement of the battery ends.

### S209

The external charging/replacement detection unit 22 turns OFF a detection flag indicating that external charging or replacement of the battery 11 has been detected. When the detection flag is turned OFF by the external charging/replacement detection unit 22, the determination control such as the replacement of the battery ends.

The above-described determination control such as battery replacement of the first embodiment makes use of a phenomenon in which the charging current decreases when the battery 11 becomes fully charged (SOC=100%) while the vehicle 10 is traveling. In the determination control such as battery replacement of the first embodiment, if the count that the current integrated value during traveling is less than the first threshold value and the average current value is less than the second threshold value exceeds the third threshold value state, it is determined that the battery 11 has been externally charged or replaced. With this method, it is possible to easily detect external charging and replacement of the battery 11 without using a voltage that fluctuates due to disturbance.

### (2) Second Example

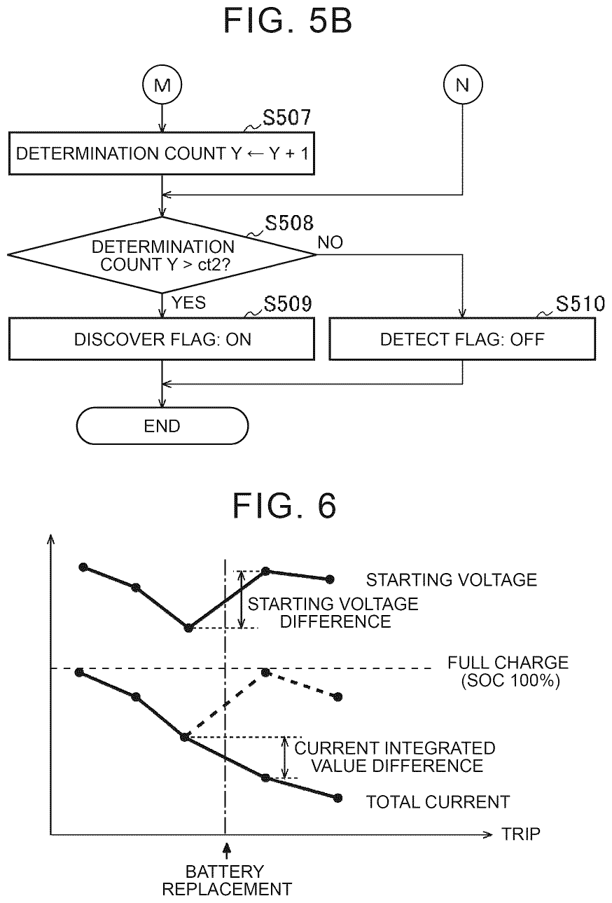

FIGS. 5A and 5B are flow charts for describing the process sequence of the second embodiment of the battery replacement or the like determination control executed by the battery management device 20. This second embodiment is a method that specializes in SOC dependency of the voltage of the battery 11 and uses the direction of the start-up voltage change and the direction of the current integrated value change. The process of FIG. 5A and the process of FIG. 5B are connected by the couplers M and N, respectively. For example, the determination control such as battery replacement illustrated in FIGS. 5A and 5B is repeatedly started every time the ignition of the vehicle 10 is turned IG-ON and the vehicle 10 is activated.

### S501

The data reception unit 21 receives data transmitted from the data transmission unit 13 of the vehicle 10. The data received by the data reception unit 21 includes at least information on the current and the voltage of the battery 11. The received data may be stored in a predetermined storage unit (not shown) or the like. When the data is received by the data reception unit 21, the process proceeds to S502.

### S502

The external charging/replacement detection unit 22 determines whether or not the parking time of the vehicle 10 prior to receiving the data in S501 is equal to or greater than a predetermined time (seventh threshold value). That is, the external charging/replacement detection unit 22 determines whether or not the time from the end of the previous activation of the vehicle 10 until the current activation has elapsed for a predetermined time or more. This determination is made to determine whether the activation voltage of the battery 11 is affected by polarization. When the external charging/replacement detection unit 22 determines that the parking time of the vehicles 10 is equal to or longer than the predetermined time (S502, Yes), the process proceeds to S503. On the other hand, when the external charging/replacement detection unit 22 determines that the parking time of the vehicles 10 is less than the predetermined time (S502, No), the process proceeds to S508.

### S503

The external charging/replacement detection unit 22 updates (derives) the integrated current value of the battery 11. Specifically, the external charging/replacement detection unit 22 calculates the charge/discharge amount (current value) of the battery 11 from the time of the previous startup to the time of the current startup based on the current (current value) of the battery 11 included in the data received by S501. Then, the calculated charge/discharge amount (current value) is added to the current integrated value of the battery 11 obtained by integrating all the charge/discharge amounts (past values) thus far. When the current integrated value of the battery 11 is updated by the external charging/replacement detection unit 22, the process proceeds to S504.

### S504

The external charging/replacement detection unit 22 derives a differential value of the starting voltage of the battery 11. Specifically, the external charging/replacement detection unit 22 derives a first voltage difference (=current value-previous value) which is a difference value between the starting voltage (current value) of the battery 11 at the time of the current startup and the starting voltage (previous value) of the battery 11 at the time of the previous startup, based on the data received by S501. When the external charging/replacement detection unit 22 derives the difference between the starting voltages, the process proceeds to S505.

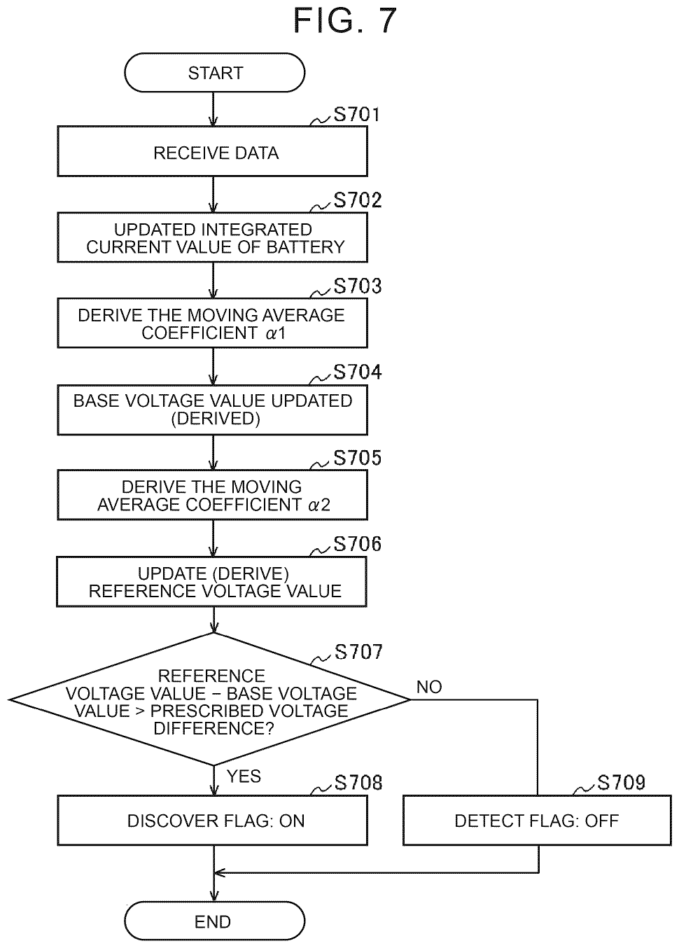

An image diagram of the difference between the starting voltages of the battery 11 derived in this S504 is shown in the upper diagram of FIG. 6. As shown in FIG. 6, the differential value (first voltage difference) of the starting voltage of the battery 11 is the voltage difference between the front and rear of each of the measured starting voltages of the battery 11.

Here, the starting voltage of the battery 11 used for deriving the first voltage difference is preferably a correction value obtained by excluding a variation factor due to temperature, current, and polarization from the measured value. The variation factor due to the temperature can be excluded by adding a value obtained by multiplying the measured value of the starting voltage of the battery 11 by the difference between the measured temperature and 25 degrees to the coefficient A based on the starting voltage at 25 degrees, which is the reference temperature, as shown in Equation 1 below. Further, the variation factor due to the current can be further excluded by adding a value obtained by multiplying a coefficient B based on the starting voltage at 40 amperes, which is the reference starting current, by the difference between 40 amperes and the measured current, to the starting voltage at which the temperature of the battery 11 is corrected, as shown in Equation 2 below. Further, the variation factor due to the polarization can be excluded by using the start-up voltage after the vehicle 10 has been parked for a predetermined period or longer (the above-described S502 process).

$$Temperature correction start voltage = Actual start voltage + coefficient A \times ( 25 ° C . - Actual tempertaure ) \qquad [ Equation 1 ]$$

$$Current Temperature Correction Start Voltage = Temperature Correction Start Voltage + Coefficient B \times ( 40 A - Actual Current ) \qquad [ Equation 2 ]$$

The external charging/replacement detection unit 22 derives a voltage conversion value of a difference between the integrated current values of the battery 11. Specifically, the external charging/replacement detection unit 22 calculates a difference value (=current value−previous value) between the integrated value (current value) of the current charged and discharged by the battery 11 by the time of the current startup and the integrated value (previous value) of the current charged and discharged by the battery 11 by the time of the previous startup, based on the current integrated value updated by S503. Then, a second voltage difference, which is a value obtained by converting the calculated difference into a voltage, is derived. This conversion is performed by dividing the difference value of the current integrated value by a predetermined coefficient (for example, “10”) for converting the change amount of the current integrated value into the change amount of the voltage. When the voltage-converted value of the difference between the current integrated values is derived by the external charging/replacement detection unit 22, the process proceeds to S506.

An image diagram of a difference value of the current integrated value of the battery 11 derived in this S505 is shown in the lower diagram of FIG. 6. As shown in FIG. 6, the difference value (before voltage conversion) between the current integrated values of the battery 11 is the difference between the current integrated values before and after each of the current integrated values of the battery 11. The difference between the current integrated values is converted into a voltage value by a coefficient. Note that the difference value of the current integrated value of the battery 11 before the voltage conversion is the same value as the charge/discharge amount (current value) of the battery 11 from the time of the previous startup to the time of the current startup, which is used for updating the current integrated value of the battery 11 in the above S503.

### S506

The external charging/replacement detection unit 22 determines whether or not the value obtained by subtracting the second voltage difference, which is the voltage conversion value of the difference between the current integrated values, from the first voltage difference, which is the difference value of the starting voltage of the battery 11, is larger than a predetermined voltage value dVce (fifth threshold value). This determination is made to determine if there is no inconsistency between the first voltage difference and the second voltage difference in which the direction of change is the same. The voltage value dVce is set to a value larger than zero (e.g., “2”) in order to avoid erroneous determination of the voltage variation. When the external charging/replacement detection unit 22 determines that the value obtained by subtracting the second voltage difference from the first voltage difference is larger than the voltage value dVce (S506, Yes), the process proceeds to S507. On the other hand, when the external charging/replacement detection unit 22 determines that the value obtained by subtracting the second voltage difference from the first voltage difference is equal to or less than the voltage value dVce (S506, No), the process proceeds to S508.

### S507

The external charging/replacement detection unit 22 increments the determination count Y for counting the count that the determination of S506 is “true” by one. The determination count Y is cleared by resetting a parameter used for, for example, another logic for determining the rise of the battery 11 based on a determination that the battery 11 has been externally charged or replaced. When the determination count Y is incremented by one by the external charging/replacement detection unit 22, the process proceeds to S508.

### S508

The external charging/replacement detection unit 22 determines whether or not the determination count Y exceeds a predetermined count ct2 (sixth threshold value). This determination is performed in order to avoid false detections caused by noises and the like, and the predetermined count ct2 is set to any value (for example, “five times”) that can enhance the determination accuracy. The count ct2 may be the same value as or different values from the count ct1 described in the first embodiment. When the external charging/replacement detection unit 22 determines that the determination count Y exceeds the count ct2 (S508, Yes), the process proceeds to S509. On the other hand, when the external charging/replacement detection unit 22 determines that the determination count Y is equal to or less than the count ct2 (S508, No), the process proceeds to S510.

### S509

The external charging/replacement detection unit 22 turns ON a detection flag indicating that external charging or replacement of the battery 11 has been detected. In response to ON of the detecting flag, the data output unit 23 can perform a required process. When the detection flag is turned ON by the external charging/replacement detection unit 22, the determination control such as the replacement of the battery ends.

### S510

The external charging/replacement detection unit 22 turns OFF a detection flag indicating that external charging or replacement of the battery 11 has been detected. When the detection flag is turned OFF by the external charging/replacement detection unit 22, the determination control such as the replacement of the battery ends.

The determination control such as battery replacement of the second embodiment described above focuses on the direction of the start-up voltage change and the direction of the current integrated value change of the battery 11. In the battery replacement or the like determination control of the second embodiment, if the difference between the differential value of the starting voltage of the battery 11 (the first voltage difference) and the voltage conversion value of the difference between the current integrated value (the second voltage difference) is larger than the fifth threshold value, it is determined that the battery 11 has been externally charged or replaced. By this method, it is possible to easily detect external charging and replacement of the battery 11 by eliminating the influence of the integration error on the integrated current value while suppressing the influence of the disturbance on the voltage.

### (3) Third Embodiment

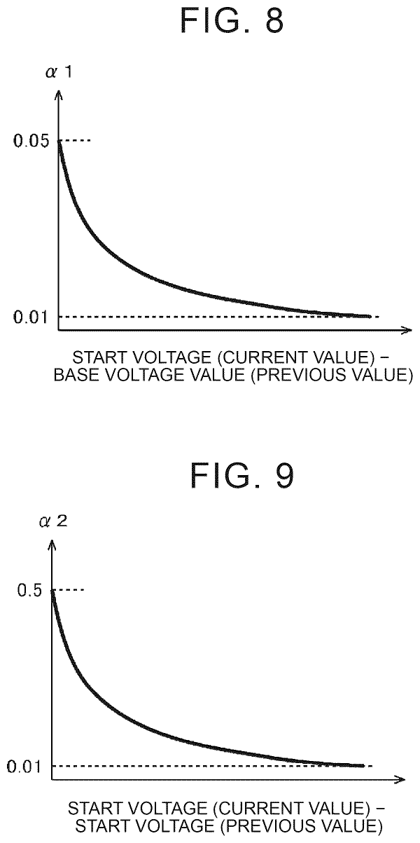

FIG. 7 is a flowchart for explaining a processing procedure of a third embodiment of determination control such as battery replacement executed by the battery management device 20. This third embodiment is a method of using the moving average value of the starting voltage. For example, the battery replacement or the like determination control illustrated in FIG. 7 is repeatedly started every time the ignition of the vehicle 10 is turned IG-ON and the vehicle 10 is activated.

### S701

The data reception unit 21 receives data transmitted from the data transmission unit 13 of the vehicle 10. The data received by the data reception unit 21 includes at least information on the current and the voltage of the battery 11. The received data may be stored in a predetermined storage unit (not shown) or the like. When the data is received by the data reception unit 21, the process proceeds to S702.

### S702

The external charging/replacement detection unit 22 updates (derives) the integrated current value of the battery 11. Specifically, the external charging/replacement detection unit 22 calculates the charge/discharge amount (current value) of the battery 11 from the time of the previous startup to the time of the current startup based on the current (current value) of the battery 11 included in the data received by S701. Then, the calculated charge/discharge amount (current value) is added to the current integrated value of the battery 11 obtained by integrating all the charge/discharge amounts (past values) thus far. When the integrated current of the battery 11 is updated by the external charging/replacement detection unit 22, the process proceeds to S703.

### S703

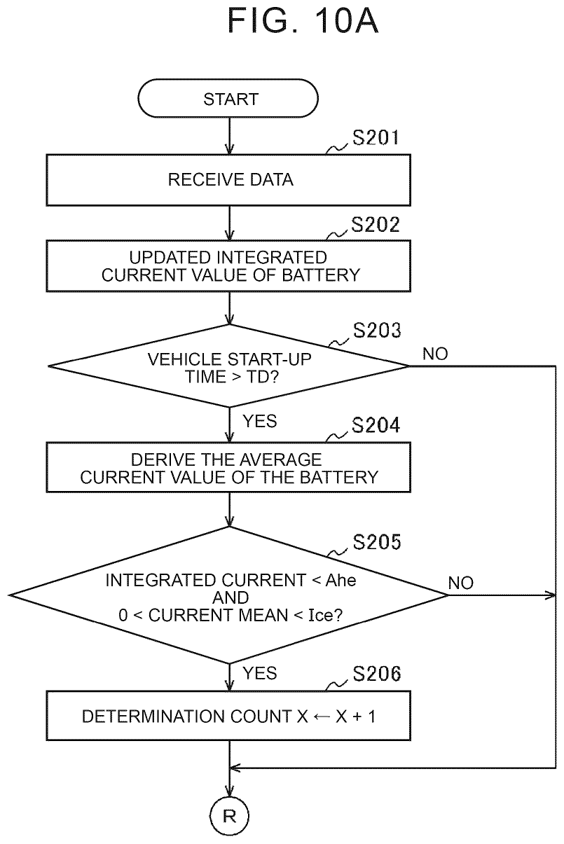

The external charging/replacement detection unit 22 derives a moving average coefficient α1 used for updating the base voltage value. The base voltage value (VEMA1) is a value of a voltage which is sequentially updated by using the moving average coefficient α1 calculated in the present S703 with a predetermined voltage of the battery 11 as an initial voltage. Examples of the initial voltage include a voltage when the battery 11 is new, a voltage when the battery is fully charged by an external charger, and the like. The moving average coefficient α1 is a coefficient that changes in accordance with a difference value between the starting voltage of the battery 11 at the time of the current startup and the base voltage value updated at the time of the previous startup, and can be, for example, a value that exponentially decreases in accordance with an increase in the difference value as shown in FIG. 8. The moving average coefficient α1 may be extracted from a data map as shown in FIG. 8 or may be calculated by a predetermined arithmetic expression. When the moving averaging factor α1 is derived by the external charging/replacement detection unit 22, the process proceeds to S704.

### S704

The external charging/replacement detection unit 22 updates (derives) the base voltage value. Specifically, the external charging/replacement detection unit 22 updates the base voltage value according to the relative difference with the starting voltage of the battery 11 according to Equation 3 below, using the moving averaging factor α1 derived by the above S703. As can be seen from Equation 3, the larger the difference between the base voltage value and the starting voltage is, the smaller the moving average coefficient α1 becomes (FIG. 8), and thus the voltage change amount of the base voltage value becomes smaller. Therefore, when the deviation between the base voltage value and the starting voltage is large, the updated base voltage value is substantially the same as the previous base voltage value even if the update is performed, and the voltage before the update is substantially maintained. When the external charging/replacement detection unit 22 updates the base voltage value, the process proceeds to S705.

$$Updated base voltage value = ( 1 - α 1 ) \times base voltage value α 1 \times starting voltage \qquad [ Equation 3 ]$$

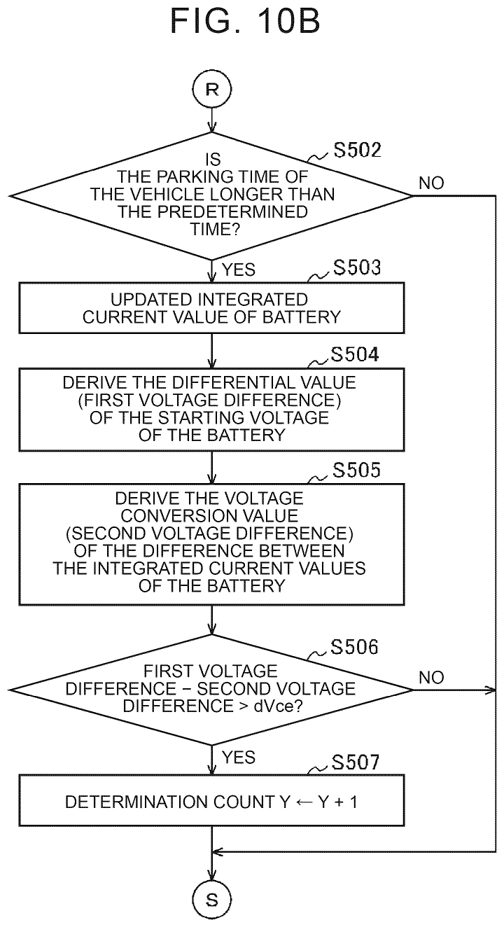

The external charging/replacement detection unit 22 derives a moving average coefficient α2 used for updating the reference voltage value. The reference voltage value (VEMA2) is a value of a voltage which is sequentially updated by using the moving average coefficient α2 calculated in the present S705 with the voltage of the battery 11 determined in advance as an initial voltage. The same value as that of the base voltage value is used as the initial voltage. The moving average coefficient α2 is a coefficient that changes in accordance with a difference value (=current value-previous value) between the starting voltage of the battery 11 at the time of the current startup and the starting voltage of the battery 11 at the time of the previous startup. The moving average coefficient α2 may be an exponentially decreasing value in accordance with an increase in the difference value, for example, as shown in FIG. 9. The moving average coefficient α2 is basically set to a value larger than the moving average coefficient α1 described above. The moving average coefficient α2 may be extracted from a data map as shown in FIG. 9 or may be calculated by a predetermined arithmetic expression. When the moving averaging factor α2 is derived by the external charging/replacement detection unit 22, the process proceeds to S706.

### S706

The external charging/replacement detection unit 22 updates (derives) the reference voltage value. Specifically, the external charging/replacement detection unit 22 uses the moving mean factor α2 derived by the above S705 to update the reference voltage value according to Equation 4 below. As can be seen from Equation 4, the larger the difference between the previous starting voltage and the current starting voltage, the smaller the moving average coefficient α2 (FIG. 9), and thus the smaller the voltage change amount of the reference voltage value. Therefore, when the starting voltage fluctuates greatly between the previous time and the current time, the updated reference voltage value is substantially unchanged from the previous reference voltage value even if the update is performed, so that the influence of noise or the like is removed. When the external charging/replacement detection unit 22 updates the reference voltage value, the process proceeds to S707.

$$Updated reference voltage value = ( 1 - α 2 ) \times reference voltage value + α 2 \times starting voltage \qquad [ Equation 4 ]$$

As described in the second embodiment, it is preferable that the starting voltage of the battery 11 used for S706 from S703 is a corrected value obtained by excluding the variation factor due to the temperature, the current, and the polarization from the measured value.

### S707

The external charging/replacement detection unit 22 determines whether or not the value obtained by subtracting the base voltage value from the reference voltage value is larger than a predetermined voltage value (eighth threshold value). This determination is made to determine whether there is a discrepancy between the reference voltage value and the base voltage value that changes the same. The predetermined voltage value can be appropriately set in accordance with the performance of the battery 11, the required detection performance, and the like. In this S707, it may be simply determined whether or not the reference voltage value is larger than the base voltage value without using a predetermined voltage value. When the external charging/replacement detection unit 22 determines that the value obtained by subtracting the base voltage value from the reference voltage value is larger than the predetermined voltage value (S707, Yes), the process proceeds to S708. On the other hand, when the external charging/replacement detection unit 22 determines that the value obtained by subtracting the base voltage value from the reference voltage value is equal to or less than the predetermined voltage value (S707, No), the process proceeds to S709.

### S708

The external charging/replacement detection unit 22 turns ON a detection flag indicating that external charging or replacement of the battery 11 has been detected. In response to ON of the detecting flag, the data output unit 23 can perform a required process. When the detection flag is turned ON by the external charging/replacement detection unit 22, the determination control such as the replacement of the battery ends.

### S709

The external charging/replacement detection unit 22 turns OFF a detection flag indicating that external charging or replacement of the battery 11 has been detected. When the detection flag is turned OFF by the external charging/replacement detection unit 22, the determination control such as the replacement of the battery ends.

In the above-described determination control such as battery replacement of the third embodiment, when the value obtained by subtracting the base voltage value from the reference voltage value is larger than the predetermined voltage value by using the moving average value of the voltage of the battery 11, it is determined that the battery 11 has been externally charged or replaced. By this method, by adjusting the moving average value of the voltage, it is possible to easily detect external charging and replacement of the battery 11 while removing the influence of disturbance on the voltage by the logic using only the voltage value.

### Application Example

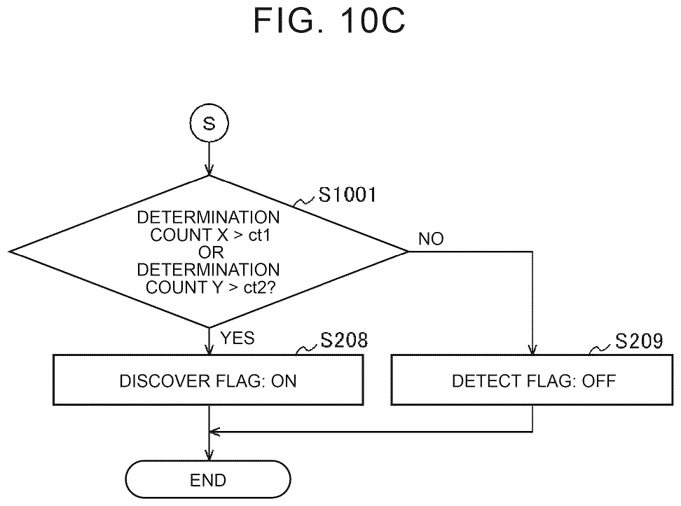

The first embodiment, the second embodiment, and the third embodiment of the determination control such as battery replacement described above can be appropriately combined and executed. As an example, a flow chart of a process sequence of determination control such as battery replacement combined with the first example and the second example is shown in FIG. 10A, FIG. 10B, and FIG. 10C. The respective processes of FIG. 10A, FIG. 10B, and FIG. 10C are connected by couplers R and S, respectively.

Among the processes in the determination control such as battery replacement of the application example, the processes having the same step numbers as those in FIG. 2, FIG. 5A, and FIG. 5B perform the same processes as those in the first embodiment and the second embodiment. Hereinafter, the determination control such as battery replacement of the application example will be described with a focus on processes different from those of the first embodiment and the second embodiment.

In FIG. 10A, when the external charging/replacement detection unit 22 determines that the vehicle start-up period is equal to or less than the time TD (S203, No), when S205 determines that the current integrated value of the battery 11 is equal to or greater than the integrated value Ahe, or that the current averaged value of the battery 11 is equal to or less than zero, or that the current value is equal to or greater than the current value Ice (S205, No), and when the determination count X is incremented by one (S206), the process proceeds to S502.

In FIG. 10B, when the external charging/replacement detection unit 22 determines that the parking time of the vehicle 10 is less than the predetermined time (S502, No), when it is determined that the value obtained by subtracting the second voltage difference from the first voltage difference is equal to or less than the voltage value dVce (S506, No), and when the determination count Y is incremented by one (S507), the process proceeds to S1001.

In S1001 shown in FIG. 10C, the external charging/replacement detection unit 22 determines whether or not the determination count X exceeds a predetermined count ct1 (third threshold value) and whether or not the determination count Y exceeds a predetermined count ct2 (sixth threshold value). Then, when the external charging/replacement detection unit 22 determines that the determination count X exceeds the count ct1 or when it determines that the determination count Y exceeds the count ct2 (S1001, Yes), the process proceeds to S208. On the other hand, when the external charging/replacement detection unit 22 determines that the determination count X does not exceed the count ct1 and the determination count Y does not exceed the count ct2 (S1001, No), the process proceeds to S209.

As described above, in the determination control such as battery replacement of the application example, if the final outcome (S1001) is “true” in either the determination based on the first embodiment or the determination based on the second embodiment, it is determined that the battery 11 has been externally charged or replaced. As a result, the accuracy of detecting that the battery has been externally charged or replaced is improved as compared with the case where any one of the embodiments is performed alone.

### Operations and Effects

As described above, according to the battery management device 20 according to the embodiment of the present disclosure, the inconsistency of the battery state (the difference in the change direction, the deviation of the value, and the like) that appears due to the fact that the parameters of the logic necessary for the management of the battery 11 are not reset when the battery 11 is externally charged or replaced is determined using information such as the integrated value, the average value, and the starting voltage of the charge and discharge current of the battery 11 that can be easily acquired.

By this control, it is possible to accurately detect that the battery 11 has been externally charged and that the battery 11 has been replaced without using a complicated equivalent circuit model in which the processing load increases.

The battery management device of the present disclosure can be used when determining that a battery mounted in a vehicle has been externally charged or replaced.

What is claimed is:

1. A battery management device configured to manage a battery mounted on a vehicle, the battery management device comprising:
an acquisition unit configured to acquire, from the vehicle, data including information on a current of the battery and information on activation of the vehicle;
a derivation unit configured to derive, based on the data, an integrated value of currents that have been charged and discharged by the battery and an average value of currents charged and discharged by the battery during a latest activation period of the vehicle; and
a determination unit configured to determine that external charging or replacement of the battery has been performed when the integrated value of the currents is smaller than a first threshold value and the average value of the currents is smaller than a second threshold value.

2. The battery management device according to claim 1, wherein:
the derivation unit is configured to derive the integrated value of the currents and the average value of the currents each time the vehicle is activated; and
the determination unit is configured to determine that the external charging or the replacement of the battery has been performed when a count of a state in which the integrated value of the currents is smaller than the first threshold value and the average value of the currents is smaller than the second threshold value is larger than a third threshold value.

3. The battery management device according to claim 1, wherein the determination unit is configured not to perform determination when the activation period of the vehicle is shorter than a fourth threshold value.

4. A battery management device configured to manage a battery mounted on a vehicle, the battery management device comprising:
an acquisition unit configured to acquire, from the vehicle, data including information on a current and a voltage of the battery when the vehicle is activated;
a derivation unit configured to derive, based on the data, a first voltage difference that is a difference value between an activation voltage of the battery at a time of current activation and an activation voltage of the battery at a time of previous activation, and a second voltage difference obtained by converting, into a voltage, a difference value between an integrated value of currents charged and discharged by the battery before the current activation and an integrated value of currents charged and discharged by the battery before the previous activation; and
a determination unit configured to determine that external charging or replacement of the battery has been performed when a value obtained by subtracting the second voltage difference from the first voltage difference is larger than a fifth threshold value.

5. The battery management device according to claim 4, wherein the derivation unit is configured to derive the first voltage difference by converting the activation voltage in a current state of the battery acquired by the acquisition unit into an activation voltage at a predetermined reference temperature of the battery and at a reference activation current.

6. The battery management device according to claim 4, wherein the determination unit is configured to determine that the external charging or the replacement of the battery has been performed when a count of a state in which the value obtained by subtracting the second voltage difference from the first voltage difference is larger than the fifth threshold value is larger than a sixth threshold value.

7. The battery management device according to claim 4, wherein the determination unit is configured not to perform determination when a period from an end of the previous activation of the vehicle to the current activation of the vehicle is smaller than a seventh threshold value.

8. A battery management device configured to manage a battery mounted on a vehicle, the battery management device comprising:
an acquisition unit configured to acquire, from the vehicle, data including information on a current and a voltage of the battery when the vehicle is activated;
a derivation unit configured to derive, based on the data, a base voltage value obtained by updating a predetermined initial voltage in accordance with a relative difference from an activation voltage of the battery at a time of activation, and a reference voltage value obtained by updating the initial voltage in accordance with a difference value between an activation voltage of the battery at a time of current activation and an activation voltage of the battery at a time of previous activation; and
a determination unit configured to determine that external charging or replacement of the battery has been performed when a value obtained by subtracting the base voltage value from the reference voltage value is larger than an eighth threshold value.

9. The battery management device according to claim 8, wherein the derivation unit is configured to derive the base voltage value by reducing a voltage change amount from a previous time to a current time as a difference between the activation voltage of the battery at the time of current activation and the base voltage value updated at the time of previous activation increases, and to derive the reference voltage value by reducing the voltage change amount from the previous time to the current time as a difference between the activation voltage of the battery at the time of current activation and the activation voltage of the battery at the time of previous activation increases.
